(19) United States
(12) Patent Application Publication
(10) Pub. No.: US 2024/0213074 A1
(43) Pub. Date: Jun. 27, 2024

(54) ENHANCED NOZZLE FOR DISAGGREGATED DIE HANDLING DURING THERMAL COMPRESSION BONDING

(71) Applicant: Intel Corporation, Santa Clara, CA (US)

(72) Inventors: Mark SALTAS, Chandler, AZ (US); Edvin CETEGEN, Chandler, AZ (US); Tony DAMBRAUSKAS, Chandler, AZ (US); Albert KAMGA, Phoenix, AZ (US); Mine KAYA, Scottsdale, AZ (US); James MELLODY, Phoenix, AZ (US); Rajesh Kumar NEERUKATTI, Chandler, AZ (US)

(21) Appl. No.: 18/089,468

(22) Filed: Dec. 27, 2022

(51) Int. Cl. H01L 21/683; B25J 15/06

(52) U.S. Cl. CPC H01L 21/6838; B25J 15/0616; H01L 2224/81203

(57) ABSTRACT

This disclosure describes nozzle designs for holding disaggregated die flat in a bonding process. The nozzle designs may have trenches extending radially outward from the center of the nozzle to the corners, such as in a snowflake pattern. The trenches may be positioned to be axially unaligned with any mold dishes of the disaggregated die when lifting the disaggregated die. The trenches may have a depth of at least 200 micrometers to allow for sufficient air flow to prevent warpage of the disaggregated die.

### TECHNICAL FIELD

This disclosure generally relates to devices, systems, and methods for thermal compression bonding for integrated circuits and, more particularly, to an enhanced nozzle for disaggregated die handling during thermal compression bonding for integrated circuits.

### BACKGROUND

Thermal compression bonding is an important process in integrated circuit packaging. As disaggregated pieces of die are able to be assembled together like a puzzle, there is a challenge in picking up the pieces of the die with a tool due to the different warpage signature and stiffness of the disaggregated die in comparison with a monolithic die.

### BRIEF DESCRIPTION OF THE DRAWINGS

FIG. 1 illustrates example bond nozzles for monolithic and disaggregated die, according to some example embodiments of the present disclosure.

FIG. 2 illustrates the effect of trench depths on nozzle suction and lift capabilities, in accordance with one or more example embodiments of the present disclosure.

FIG. 3 illustrates example nozzle designs with different trench flow areas, in accordance with one or more example embodiments of the present disclosure.

FIG. 4 illustrates an example graph 400 showing the effects of trench area on computational fluid dynamics, in accordance with one or more example embodiments of the present disclosure.

FIG. 5 illustrates example forces acting upon a die before and after solder melt, in accordance with one or more example embodiments of the present disclosure.

FIG. 6 illustrates the effects of trench layout on flux ingestion, in accordance with one or more example embodiments of the present disclosure.

FIG. 7A illustrates an example vacuum trench grid layout, in accordance with one or more example embodiments of the present disclosure.

FIG. 7B illustrates the example vacuum trench snowflake layout of FIG. 1, in accordance with one or more example embodiments of the present disclosure.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

In semiconductor fabrication, thermal compression bonding (TCB) is an important technique in which heat and force may be applied to a die to form a bond with a substrate. As newer designs use disaggregated die instead of monolithic die, it is becoming more challenging to pick up the disaggregated die due to the different warpage signature and in-plane stiffness of the disaggregated die in comparison with a monolithic die.

Some TCB design rules are based on the intended die size of a monolithic die. The function of the nozzle trenches is to apply vacuum pressure against a smooth die surface. Warpage to monolithic die is small enough that the applied trench vacuum can acquire a presented die and hold it flat against the nozzle. It is important that when a die is picked up that it be flat against the tool nozzle, so it is important to minimize warpage of the die when picked up to facilitate the thermal bonding process. As the die increase in size, there are more challenges with disaggregated die warpage when picked up by a TCB tool nozzle. Warpage may change with temperature, and the warpage may be so small that it may not be noticeable to the human eye (e.g., 500-800 micrometers), so it may be critical to avoid the warpage. Disaggregated die typically have large form factors with complex warpage topographies and a non-uniform sealing surface. Some nozzles are unable to apply sufficient vacuum onto the disaggregated die to flatten it against the bond nozzle.

In one or more embodiments, the present disclosure solves the problem of TCB bond nozzles acquiring and holding large form-factor disaggregated die flat against the bond nozzle. Disaggregated die are a nonhomogeneous composition of silicon die, solder, epoxy, and mold materials (e.g., compared to a monolithic die with plain silicon). This causes complex warpage topographies and in-plane bonding stiffness within the die that needs to be pulled flat with vacuum against the nozzle to insure uniform good joint formation and chip gap. The enhanced nozzle features herein provide functionality to lift the outer corners/edges of the die against the nozzle, minimize the risk of flux ingestion between the bond nozzle/die interface, and minimize the thermal gradients experienced during the bonding process.

In one or more embodiments, the present disclosure provides a group of TCB bond nozzle design features that developed and implement during test vehicles with disaggregated die. Application of some design rules resulted in challenges because the traditional nozzle design could not flatten and hold the disaggregated die flat against the nozzle due to the warpage topography. The warpage may be reduced to less than 15 micrometers, for example (e.g., distance from bent/curved corner to apex).

In one or more embodiments, the enhanced TCB nozzles for disaggregated die may have multiple features. First, the nozzle trench area should be sized to provide the maximum air flow though the trench and over the top side of the die corner. This enables a Bernoulli effect to create a pressure differential between the top/bottom surface and lift the die corner against the nozzle surface. After the die is pulled flat against the nozzle, the trench volume evacuates and acts as a tradition vacuum nozzle. An issue with traditional nozzles is that the trench depth is too shallow to pull enough air flow over the die surface. A key is to design the trench dimension such that flow field does not become fully developed along the length of the trench. This requires a significant increase in the trench depth for disaggregated die nozzles. Recent disaggregated die nozzle designs utilize computational fluid dynamic (CFD) modeling to validate that trench dimensions facilitate sufficient vacuum flow over the die.

In one or more embodiments, for the enhanced TCB nozzles for disaggregated die, total trench suction area in contact with the die is critical. Prior to solder melt, the solid solder exerts a reactive force to the applied bond head force. These two forces sandwich the disaggregated die flat between the solder bump and bond nozzle. The reactive solder force becomes minimal once solder melt occurs in the TCB process. The flattened disaggregated die acts as a flattened wave spring that tries to return to its pre-bonded topography. If the suction area applied to the die is too small, the die's internal spring force will push the die away from the nozzle. The result is failed solder joints resulting in non-contact open (NCO) and massive solder bump bridging (MSBB).

In one or more embodiments, for the enhanced TCB nozzles for disaggregated die, the placement location of the trench across the disaggregated die is critical to avoid flux ingestion which results in flux-on-die. Disaggregated dies contain mold streets between the silicon dies. The top side grind process causes a dishing effect between the silicon. An optimized grinding process results in dishing of <2 um; however, this is enough space to cause flux ingestion if the trench lane is centered above the mold street. The solution deployed is to align trench lanes along mold streets. When more suction area is required, creative patterns can be incorporated.

In one or more embodiments, for the enhanced TCB nozzles for disaggregated die, the trench layout must be designed to minimize a significant die/solder temperature differential from the die center to corner. Thermocouple measurements on Empire Mine substrates resulted in a 50 degree C. temperature gradient from the die center to corner. This required a higher peak bond head heater temperature to ensure that the solder melted around the die corner region. The root cause of the thermal gradient is the high thermal resistance that occurs in the nozzle as the thermal energy conducts above the deep vacuum trenches. This becomes more severe as additional trenches are required to ensure that the nozzle holds the die. A solution is to create a trench layout that is radial and not rectangular. This allows heat flow to easily conduct energy from the center to the nozzle with minimized thermal resistance.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

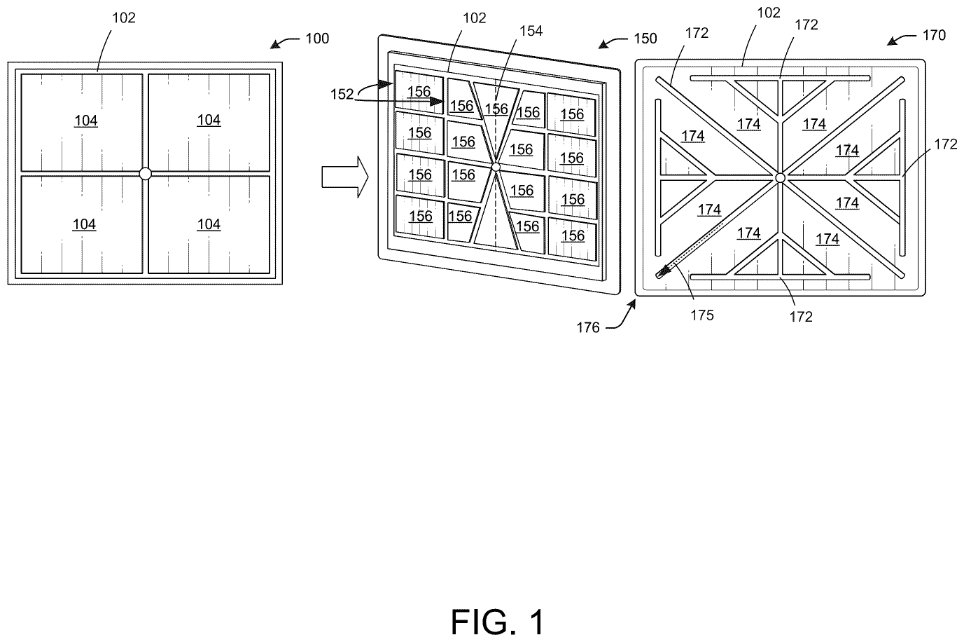

FIG. 1 illustrates example bond nozzles for monolithic and disaggregated die, according to some example embodiments of the present disclosure.

Referring to FIG. 1, a bond nozzle 100 for monolithic die is shown having a trench flow area 102 (e.g., indented into the page as a trench) surrounding multiple portions 104 (e.g., extending further out from the page relative to the trench flow area 102). A bond nozzle 150 for disaggregated die is shown having the trench flow area 102 and an additional trench suction area 152 (e.g., indented into the page as a trench) and a trench “keep-out” zone (KOZ) 154 to prevent flux ingestion, the additional trench suction area 152 surrounding multiple portions 156 (e.g., extending further out from the page relative to the trench suction area 152). A bond nozzle snowflake layout 170 for disaggregated die also is shown as having the trench flow area 102 and an additional trench suction area 172 (e.g., indented into the page as a trench relative to portions 174). The heat flow 175 to the nozzle corner 176 may be minimized to avoid warping. The bond nozzle 110 and the bond nozzle 150 use what may be referred to as a “checkerboard” pattern, whereas the bond nozzle 170 uses what may be referred to as a “snowflake” pattern that may minimize thermal resistance from the center to the corner (e.g., dropping the temperature difference between die center and corner) by having the trench suction area 172 extending linearly (e.g., radially from the center) toward the corner nozzle 176 from the center (e.g., minimizing the distance from the center to corner 176).

In one or more embodiments, the trench suction area 152 of the bond nozzle 150 and the trench suction area 172 the bond nozzle snowflake layout 170 may be sized to provide the maximum air flow though the trench and over the top side of the die corner. This enables the Bernoulli effect to create a pressure differential between the top/bottom surface and lift the die corner against the nozzle surface. After the die is pulled flat against the nozzle, the trench volume evacuates and acts as a tradition vacuum nozzle. The trench dimension may be such that flow field does not become fully developed along the length of the trench. This requires a significant increase in the trench depth for disaggregated die nozzles. In addition, the trench suction area 152 and the trench suction area 172 being in contact with the die is critical, as is the placement of the trench suction area 152 and the trench suction area 172 to avoid flux ingestion (e.g., by not aligning the trench suction area with the dished mold street between stacked die). The trench layout of trench suction area 152 and the trench suction area 172 may be designed to minimize a significant die/solder temperature differential from die center to corner.

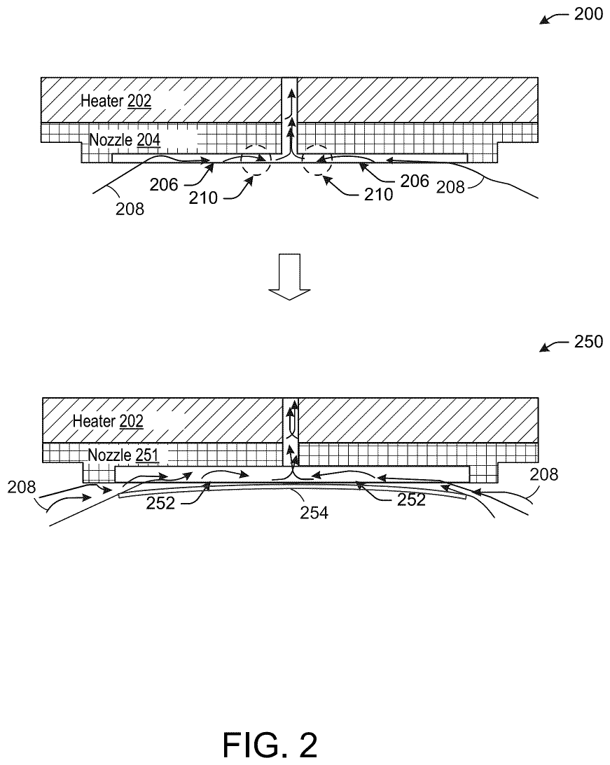

FIG. 2 illustrates the effect of trench depths on nozzle suction and lift capabilities, in accordance with one or more example embodiments of the present disclosure.

Referring to FIG. 2, a TCB design 200 may include a heater 202 and a nozzle 204. The lack of depth of the nozzle 204 trenches 206 restricts air flow 208 (e.g., in a choked flow zone 210), preventing the nozzle 204 from pulling enough air to create suction and lift a die against the nozzle 204.

Still referring to FIG. 2, a TCB design 250 may include the heater 202 and a nozzle 251 with trenches 252 having a depth greater than the depth of the trenches 252. The greater trench depth allows for more vacuum flow area, resulting in sufficient air flow 208 to create suction and lift on a die 254 against the nozzle 251.

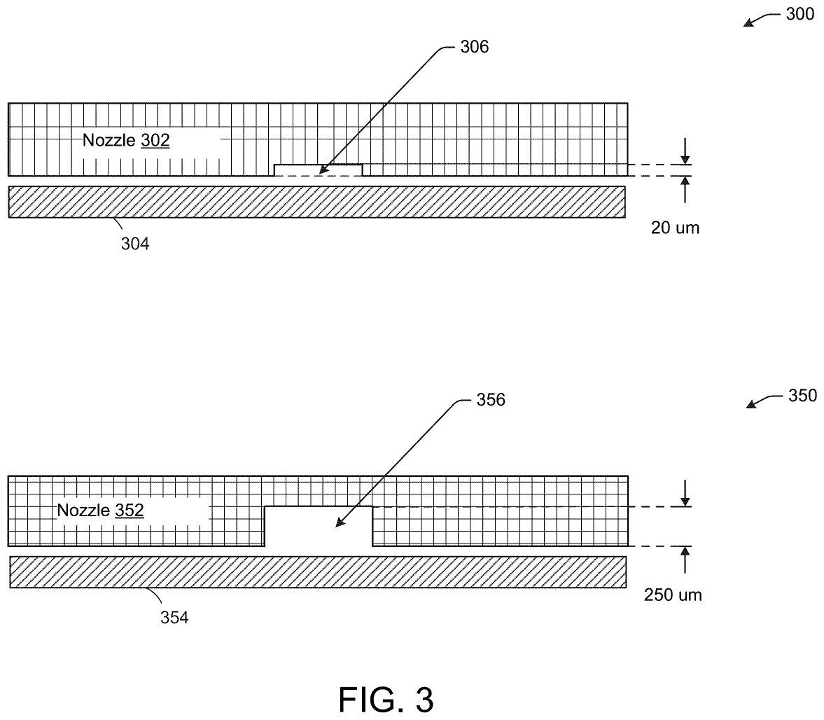

FIG. 3 illustrates example nozzle designs with different trench flow areas, in accordance with one or more example embodiments of the present disclosure.

Referring to FIG. 3, a nozzle design 300 may include a nozzle 302 for lifting a monolithic die 304 (e.g., using vacuum suction via air flow through a vacuum trench 306). As shown, the vacuum trench 306 may be 20 micrometers in depth (e.g., between the nozzle 302 and the monolithic die 304).

Still referring to FIG. 3, a nozzle design 350 may include a nozzle 352 for lifting disaggregated die 354 (e.g., using vacuum suction via air flow through a vacuum trench 356). The vacuum trench 356 as shown may be 250 micrometers in depth (e.g., between the nozzle 352 and the disaggregated die 354), allowing for more flow and better suction of the disaggregated die 354 by the nozzle 352.

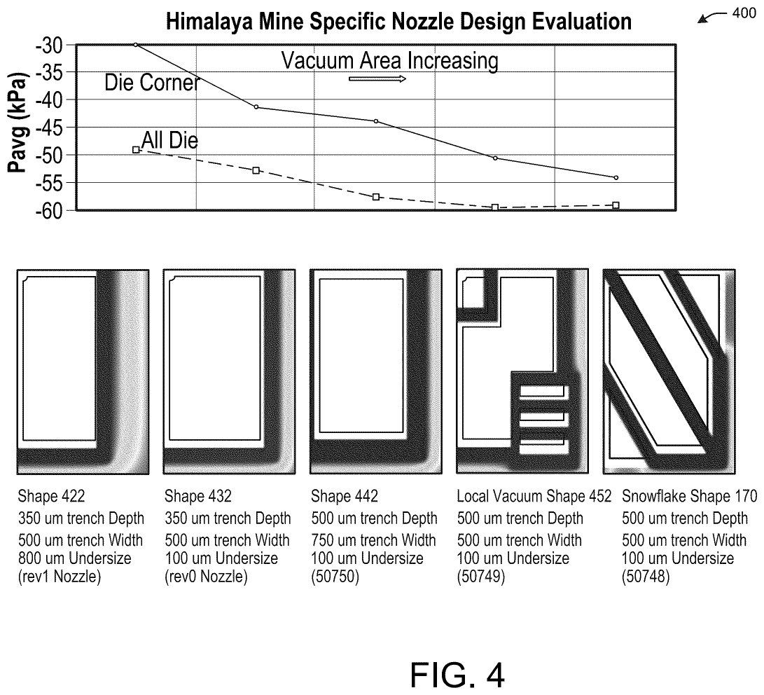

FIG. 4 illustrates an example graph 400 showing the effects of trench area on computational fluid dynamics, in accordance with one or more example embodiments of the present disclosure.

Referring to FIG. 4, the graph 400 shows that as the vacuum trench area increases (e.g., from left to right on the page), the vacuum suction at the corner of a die and for the entire die decrease, with different nozzle designs resulting in varying differences between die corner suction and suction at the rest of the die. In the example designs, a nozzle with shape 422 may have a 350 micrometer trench depth, 500 micrometer trench width, and 800 micrometer nozzle undersize. A nozzle with shape 432 may have a 350 micrometer trench depth, 500 micrometer trench width, and 100 micrometer nozzle undersize. A nozzle with shape 442 may have a 500 micrometer trench depth, 750 micrometer trench width, and 100 micrometer nozzle undersize. A nozzle with shape 452 may have a 500 micrometer trench depth, 500 micrometer trench width, and 100 micrometer nozzle undersize. A nozzle with the snowflake layout 170 of FIG. 1 may have a 500 micrometer trench depth, 500 micrometer trench width, and 100 micrometer nozzle undersize.

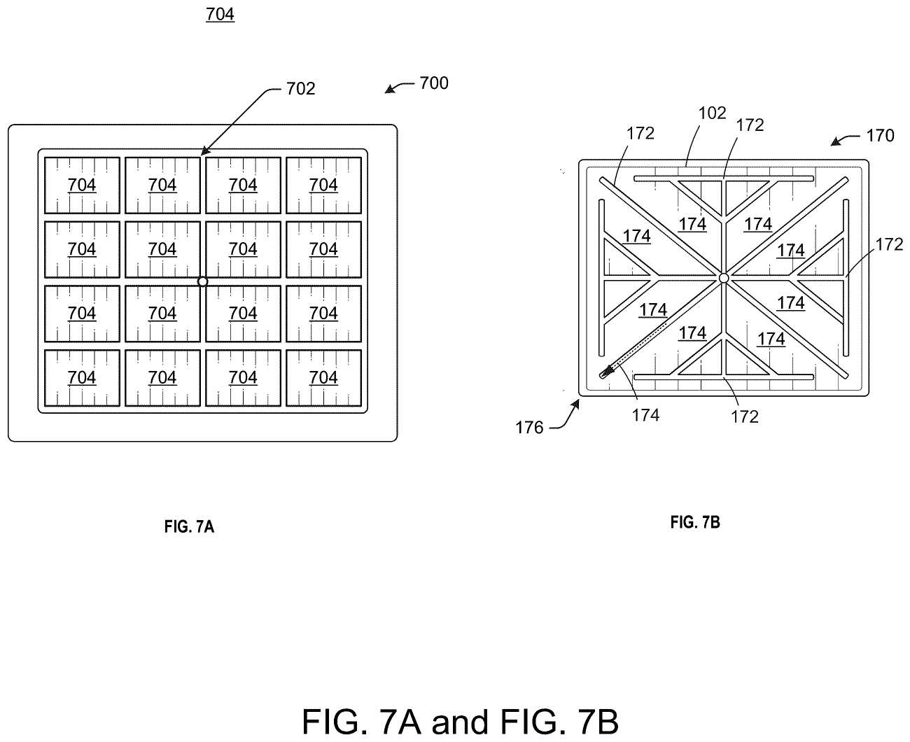

Still referring to FIG. 4, as shown by the graph 400, the snowflake shape 462 nozzle design (e.g., as shown by the bond nozzle snowflake layout 170 and in FIG. 7B) reduces the center-to-corner suction difference, reducing the chance of warpage at the corners of a die being lifted by the nozzle.

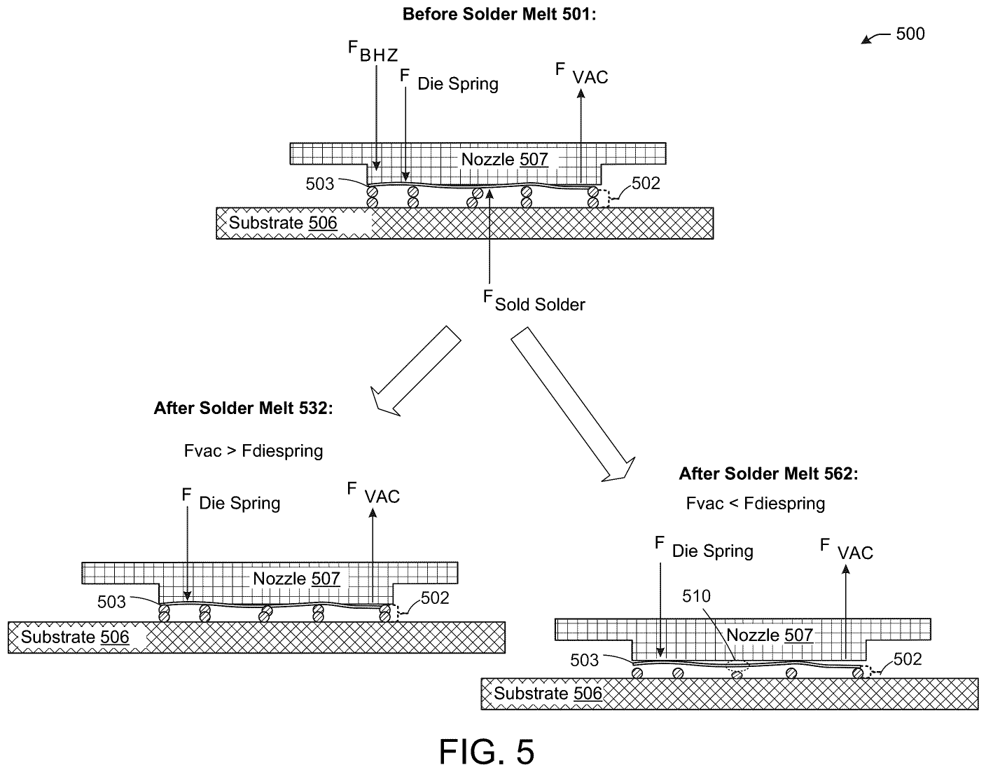

FIG. 5 illustrates example forces acting upon a die before and after solder melt, in accordance with one or more example embodiments of the present disclosure.

Referring to FIG. 5, before solder melts 501 (e.g., solder 501 connecting a disaggregated die 503 to a substrate 506), multiple forces may be applied to the disaggregated die 503 in multiple directions. For example, as shown, a bond head force F_{BHZ} (e.g., a force applied by a bond head) and a die spring force F_{DieSpring} may be applied downward, and a vacuum force F_{VAC} may be applied upward (e.g., from the vacuum suction from a nozzle 507 lifting the disaggregated die 503). As the solder 502 melts, internal energy in the disaggregated die 503 may result in warpage of the disaggregated die 503.

After solder melt 532, when the F_{VAC} is greater than the F_{DieSpring} (e.g., due to the enhanced nozzle designs described herein for the nozzle 507, in particular, a greater trench suction area in contact with the disaggregated die 503), warpage of the disaggregated die 503 may be avoided. After solder melt 562, when the F_{VAC} is less than the F_{DieSpring}, warpage to the disaggregated die 503 may occur.

Total trench suction area in contact with the die is critical. Prior to solder melt, the solid solder exerts a reactive force to the applied bond head force. These two forces sandwich the disaggregated die flat between the solder bump and bond nozzle. The reactive solder force becomes minimal once solder melt occurs in the TCB process. The flattened disaggregated die acts as a flattened wave spring that tries to return to its pre-bonded topography. If the suction area applied to the die is too small, the die's internal spring force will push the die away from the nozzle as shown in FIG. 5. The result is failed solder joints resulting in non-contact open (NCO) and massive solder bump bridging (MSBB).

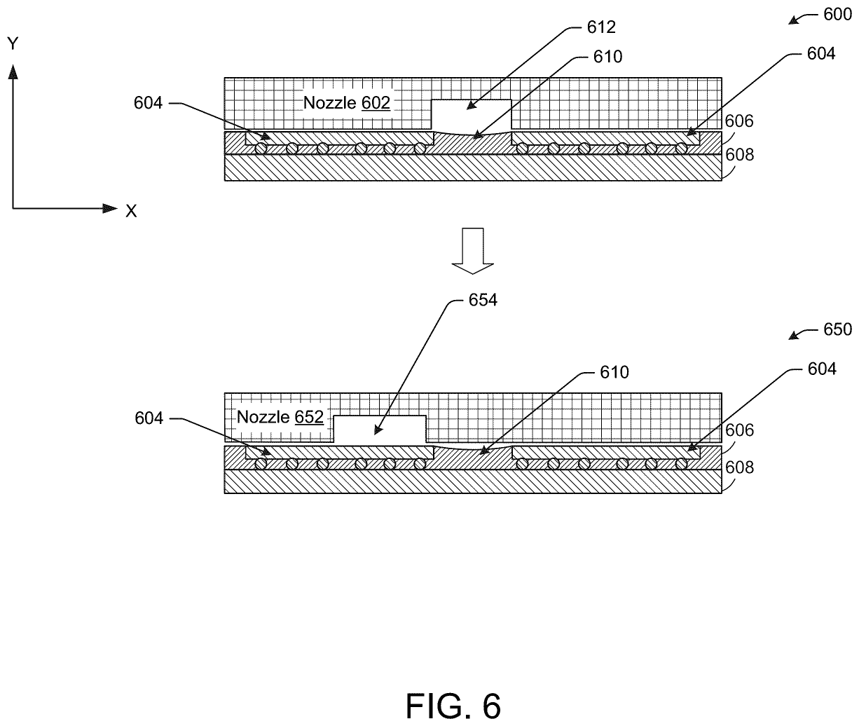

FIG. 6 illustrates the effects of trench layout on flux ingestion, in accordance with one or more example embodiments of the present disclosure.

Referring to FIG. 6, the placement location of the trench across the disaggregated die is critical to avoid flux ingestion which results in flux-on-die. A nozzle design 600 including a nozzle 602 may lift stacked die 604 (e.g., disaggregated die) that may use a molding material 606 between the respective die 604. An interposer 608 below the stacked die 604 is shown. The top side (e.g., the side of the die 604 proximal to the nozzle 602) grind process may cause a dishing effect between the silicon of the die 604 (e.g., resulting in a curved mold street 610). When a trench 612 of the nozzle 602 aligns axially (e.g., along the X-axis) with the mold street 610, the result may be a risk of flux on the die 604 (e.g., “flux ingestion”).

Still referring to FIG. 6, a nozzle design 650 including a nozzle 652 whose trench 654 is not axially aligned with the mold street 610 may avoid or at least reduce the risk of flux on the die 604.

FIG. 7A illustrates an example vacuum trench grid layout 700, in accordance with one or more example embodiments of the present disclosure.

Referring to FIG. 7, the vacuum trench grid layout 700 includes trenches 702 surrounding multiple portions 704 (e.g., the portions 704 are raised—coming out of the page—whereas the trenches 702 are indented into the page).

FIG. 7B illustrates the example vacuum trench snowflake layout 170 of FIG. 1, in accordance with one or more example embodiments of the present disclosure.

Referring to FIGS. 7A and 7B, the trench layout should be designed to minimize a significant die/solder temperature differential from the die center to corner. Thermocouple measurements on some substrates resulted in a 50 degree C. temperature gradient from the die center to corner. This required a higher peak bondhead heater temperature to ensure that the solder melted around the die corner region. The root cause of the thermal gradient is the high thermal resistance that occurs in the nozzle as the thermal energy conducts above the deep vacuum trenches. This becomes more severe as additional trenches are required to ensure that the nozzle holds the die. The solution is to create a trench layout that is radial (e.g., FIG. 7B) and not rectangular. This allows heat flow to easily conduct energy from the center to the nozzle with minimized thermal resistance.

It is understood that the above descriptions are for purposes of illustration and are not meant to be limiting.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

The word “exemplary” is used herein to mean “serving as an example, instance, or illustration.” Any embodiment described herein as “exemplary” is not necessarily to be construed as preferred or advantageous over other embodiments.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

The following examples pertain to further embodiments.

Example 1 may include a nozzle for holding and keeping disaggregated die flat during bonding, the nozzle comprising: vacuum trenches configured to allow a flow of air associated with generating a vacuum suction for lifting disaggregated die, the vacuum trenches having a depth of at least 200 micrometers, wherein the vacuum trenches are positioned to be axially unaligned with any mold dishes of the disaggregated die when lifting the disaggregated die.

Example 2 may include the nozzle of claim 1, wherein a depth of the vacuum trenches is at least 250 micrometers.

Example 3 may include the nozzle of claim 1, wherein a depth of the vacuum trenches is at least 500 micrometers.

Example 4 may include the nozzle of claim 1, wherein the vacuum trenches extend radially from the center of the nozzle outward toward the corners of the nozzle.

Example 5 may include the nozzle of claim 4, wherein the vacuum trenches do not reach the corners of the nozzle.

Example 6 may include the nozzle of claim 4, wherein the vacuum trenches form a snowflake pattern.

Example 7 may include the nozzle of claim 4, wherein the vacuum trenches are not in a rectangular pattern.

Example 8 may include the nozzle of claim 1, wherein a width of the vacuum trenches is at least 250 micrometers.

Example 9 may include the nozzle of claim 1, wherein a width of the vacuum trenches is at least 500 micrometers.

Example 10 may include a nozzle for holding and keeping disaggregated die flat during bonding, the nozzle comprising: vacuum trenches configured to allow a flow of air associated with generating a vacuum suction for lifting disaggregated die, wherein the vacuum trenches extend radially from the center of the nozzle outward toward the corners of the nozzle in a snowflake pattern.

Example 11 may include the nozzle of claim 10, wherein a depth of the vacuum trenches is at least 250 micrometers.

Example 12 may include the nozzle of claim 10, wherein a depth of the vacuum trenches is at least 500 micrometers.

Example 13 may include the nozzle of claim 10, wherein the vacuum trenches are positioned to be axially unaligned with any mold dishes of the disaggregated die when lifting the disaggregated die.

Example 14 may include the nozzle of claim 10, wherein the vacuum trenches do not reach the corners of the nozzle.

Example 15 may include the nozzle of claim 10, wherein a width of the vacuum trenches is at least 500 micrometers.

Example 16 may include a nozzle for holding and keeping disaggregated die flat during bonding, the nozzle comprising: vacuum trenches configured to allow a flow of air associated with generating a vacuum suction for lifting disaggregated die, wherein the vacuum trenches extend radially from the center of the nozzle outward toward the corners of the nozzle.

Example 17 may include the nozzle of claim 15, wherein a depth of the vacuum trenches is at least 250 micrometers.

Example 18 may include the nozzle of claim 15, wherein a depth of the vacuum trenches is at least 500 micrometers.

Example 19 may include the nozzle of claim 15, wherein the vacuum trenches are positioned to be axially unaligned with any mold dishes of the disaggregated die when lifting the disaggregated die.

Example 20 may include the nozzle of claim 15, wherein the vacuum trenches do not reach the corners of the nozzle.

Embodiments according to the disclosure are in particular disclosed in the attached claims directed to designs, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A nozzle for holding and keeping disaggregated die flat during bonding, the nozzle comprising:
vacuum trenches configured to allow a flow of air associated with generating a vacuum suction for lifting disaggregated die, the vacuum trenches having a depth of at least 200 micrometers,
wherein the vacuum trenches are positioned to be axially unaligned with any mold dishes of the disaggregated die when lifting the disaggregated die.

2. The nozzle of claim 1, wherein a depth of the vacuum trenches is at least 250 micrometers.

3. The nozzle of claim 1, wherein a depth of the vacuum trenches is at least 500 micrometers.

4. The nozzle of claim 1, wherein the vacuum trenches extend radially from the center of the nozzle outward toward the corners of the nozzle.

5. The nozzle of claim 4, wherein the vacuum trenches do not reach the corners of the nozzle.

6. The nozzle of claim 4, wherein the vacuum trenches form a snowflake pattern.

7. The nozzle of claim 4, wherein the vacuum trenches are not in a rectangular pattern.

8. The nozzle of claim 1, wherein a width of the vacuum trenches is at least 250 micrometers.

9. The nozzle of claim 1, wherein a width of the vacuum trenches is at least 500 micrometers.

10. A nozzle for holding and keeping disaggregated die flat during bonding, the nozzle comprising:
vacuum trenches configured to allow a flow of air associated with generating a vacuum suction for lifting disaggregated die,
wherein the vacuum trenches extend radially from the center of the nozzle outward toward the corners of the nozzle in a snowflake pattern.

11. The nozzle of claim 10, wherein a depth of the vacuum trenches is at least 250 micrometers.

12. The nozzle of claim 10, wherein a depth of the vacuum trenches is at least 500 micrometers.

13. The nozzle of claim 10, wherein the vacuum trenches are positioned to be axially unaligned with any mold dishes of the disaggregated die when lifting the disaggregated die.

14. The nozzle of claim 10, wherein the vacuum trenches do not reach the corners of the nozzle.

15. The nozzle of claim 10, wherein a width of the vacuum trenches is at least 500 micrometers.

16. A nozzle for holding and keeping disaggregated die flat during bonding, the nozzle comprising:
vacuum trenches configured to allow a flow of air associated with generating a vacuum suction for lifting disaggregated die,
wherein the vacuum trenches extend radially from the center of the nozzle outward toward the corners of the nozzle.

17. The nozzle of claim 15, wherein a depth of the vacuum trenches is at least 250 micrometers.

18. The nozzle of claim 15, wherein a depth of the vacuum trenches is at least 500 micrometers.

19. The nozzle of claim 15, wherein the vacuum trenches are positioned to be axially unaligned with any mold dishes of the disaggregated die when lifting the disaggregated die.

20. The nozzle of claim 15, wherein the vacuum trenches do not reach the corners of the nozzle.
